(19) United States
(12) Patent Application Publication
(10) Pub. No.: US 2023/0180447 A1
(43) Pub. Date: Jun. 8, 2023

(54) EMC MATERIAL FOR THERMAL TRANSPORT AND VIBRATION DAMPENING

(71) Applicant: International Business Machines Corporation, Armonk, NY (US)

(72) Inventors: Mehdi Hamid Vishkasougheh, Rochester, MN (US); Eric J. Campbell, Rochester, MN (US); Kevin O'Connell, Rochester, MN (US); Arshad Alfoqaha, Eden Prairie, MN (US)

(21) Appl. No.: 17/643,294

(22) Filed: Dec. 8, 2021

(51) Int. Cl. H05K 9/00

(52) U.S. Cl. CPC H05K 9/0086; H05K 9/0007

(57) ABSTRACT

Embodiments relate to materials and methods for manufacturing the materials for an enclosure that houses one or more electronic devices. In some embodiments, the materials include a tuned micro-lattice that includes one or more metallic materials defining a micro-lattice configuration. In some embodiments, the one or more metallic materials extend over at least a portion of an elastomeric material. In some embodiments, the materials include a tuned composite metallic foam including one or more metallic materials. A first portion of the foam has a first porosity and a second portion of the foam has a second porosity. In some embodiments, the materials for the enclosure are one or more of a gasket and a coating that extends over a least a portion of an interior portion of the enclosure.

### BACKGROUND

The present disclosure relates to materials for electronic devices' enclosures, and, more specifically, to electromagnetic compatibility (EMC) gasket material for thermal transport and vibration dampening.

Many known enclosures house modern electronic devices therein. At least some of these modern electronic devices generate EMI and RFI and waste heat, while the devices are susceptible to vibration from external sources.

### SUMMARY

One or more materials and methods are provided for enclosures that house electronic devices.

In one aspect, a material for an enclosure that houses one or more electronic devices is presented. The material includes a tuned micro-lattice that includes one or more metallic materials defining a micro-lattice configuration. The material for the enclosure is one or more of a gasket and a coating that extends over a least a portion of an interior portion of the enclosure.

In another aspect, a material for an enclosure that houses one or more electronic devices is presented. The material includes a tuned composite metallic foam including one or more metallic materials. A first portion of the foam has a first porosity and a second portion of the foam has a second porosity. The material for the enclosure is one or more of a gasket and a coating that extends over a least a portion of an interior portion of the enclosure.

In yet another aspect, a method for manufacturing a material for an enclosure that houses one or more electronic devices is provided. The method includes generating a metallic micro-lattice structure and filling at least a portion of the metallic micro-lattice structure with an elastomeric material.

The present Summary is not intended to illustrate each aspect of every implementation of, and/or every embodiment of the present disclosure. These and other features and advantages will become apparent from the following detailed description of the present embodiment(s), taken in conjunction with the accompanying drawings.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are illustrative of certain embodiments and do not limit the disclosure.

FIG. 1 is a block schematic diagram illustrating a computer system enclosure, in accordance with some embodiments of the present disclosure.

FIG. 2 is a flowchart illustrating a process for manufacturing a tuned micro-lattice material shown in FIG. 1, in accordance with some embodiments of the present disclosure.

FIG. 3 is a block schematic diagram illustrating a non-metallic micro-lattice template, in accordance with some embodiments of the present disclosure.

FIG. 4A is a block schematic diagram illustrating a metallic micro-lattice, in accordance with some embodiments of the present disclosure.

FIG. 4B is a block schematic diagram illustrating a portion of the tuned micro-lattice material, in accordance with some embodiments of the present disclosure.

FIG. 5 is a flowchart illustrating a process for manufacturing a tuned composite metallic foam, in accordance with some embodiments of the present disclosure.

FIG. 6 is a diagram illustrating a manufactured tuned composite metallic foam, in accordance with some embodiments of the present disclosure.

FIG. 7 is a block schematic diagram illustrating a cutaway and amplified view of the manufactured tuned composite metallic foam shown in FIG. 6, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the particular embodiments described. On the contrary, the intention is to cover all modifications, equivalents, and alternatives falling within the spirit and scope of the present disclosure.

### DETAILED DESCRIPTION

Aspects of the present disclosure relate to gaskets for enclosures that house electronic devices. While the present disclosure is not necessarily limited to such applications, various aspects of the disclosure may be appreciated through a discussion of various examples using this context.

It will be readily understood that the components of the present embodiments, as generally described and illustrated in the Figures herein, may be arranged and designed in a wide variety of different configurations. Thus, the following details description of the embodiments of the apparatus, system, method, and computer program product of the present embodiments, as presented in the Figures, is not intended to limit the scope of the embodiments, as claimed, but is merely representative of selected embodiments.

Reference throughout this specification to “a select embodiment,” “at least one embodiment,” “one embodiment,” “another embodiment,” “other embodiments,” or “an embodiment” and similar language means that a particular feature, structure, or characteristic described in connection with the embodiment is included in at least one embodiment. Thus, appearances of the phrases “a select embodiment,” “at least one embodiment,” “in one embodiment,” “another embodiment,” “other embodiments,” or “an embodiment” in various places throughout this specification are not necessarily referring to the same embodiment.

The illustrated embodiments will be best understood by reference to the drawings, wherein like parts are designated by like numerals throughout. The following description is intended only by way of example, and simply illustrates certain selected embodiments of devices, systems, and processes that are consistent with the embodiments as claimed herein.

Many known enclosures house modern electronic devices therein. At least some of these modern electronic devices generate EMI, RFI and waste heat, while the devices are susceptible to vibration from external sources. Each electronic device, and any electrical devices such as cables, wires, motors, and the like also inside the enclosure, generate a unique EMI/RFI signature. In some configurations, there are multiple enclosures in close proximity of each other, each with devices that emanate their own unique EMI/RFI signatures, and the EMI/RFI from one enclosure may be deleterious to the devices in a nearby enclosure. In at least some traditional server and computer applications, traditional EMC gaskets are used to shield electromagnetic radiation from escaping and entering the server/computer enclosure. However, traditional EMC gaskets do not provide an airflow path sufficient to allow hot air to escape the enclosure. In addition, such traditional EMC gaskets do not have sufficient mechanical properties to provide significant vibration dampening from external sources to the respective enclosures. In some known enclosure configurations, modern EMC gaskets are manufactured from a metal fabric positioned over a polymer foam, where the metal employed is known to absorb at least a portion of the EMI/RFI emissions generated in the respective enclosure. However, known manufacturing methods of known metallic EMC gaskets are not geared toward gaskets unique to each individual enclosure and the electronic devices therein. Therefore, such known metallic EMC gaskets do not optimize all desired properties of the EMC gaskets that include dampening of EMI/RFI release into the environment external to the enclosure, dampening of EMI/RFI intrusion from the external environment into the enclosure, transport of waste heat from the enclosure, and dampening of vibration energy into the enclosure.

Accordingly, at least some embodiments of the present disclosure include methods for manufacturing EMC gaskets from a metallic micro-lattice where the metal is configured to absorb some predetermined portion of the EMI/RFI emissions generated within the respective enclosure. Further, such manufacturing methods generate EMC gaskets that are unique to each individual enclosure and the electronic devices therein. In this way, some embodiments of the present disclosure generate metallic micro-lattice EMC gaskets that are uniquely configured to improve the dampening of EMI/RFI release into the ambient environment, dampening of EMI/RFI intrusion from the ambient environment, transport of waste heat from the enclosure, and dampening of vibration energy into the enclosure.

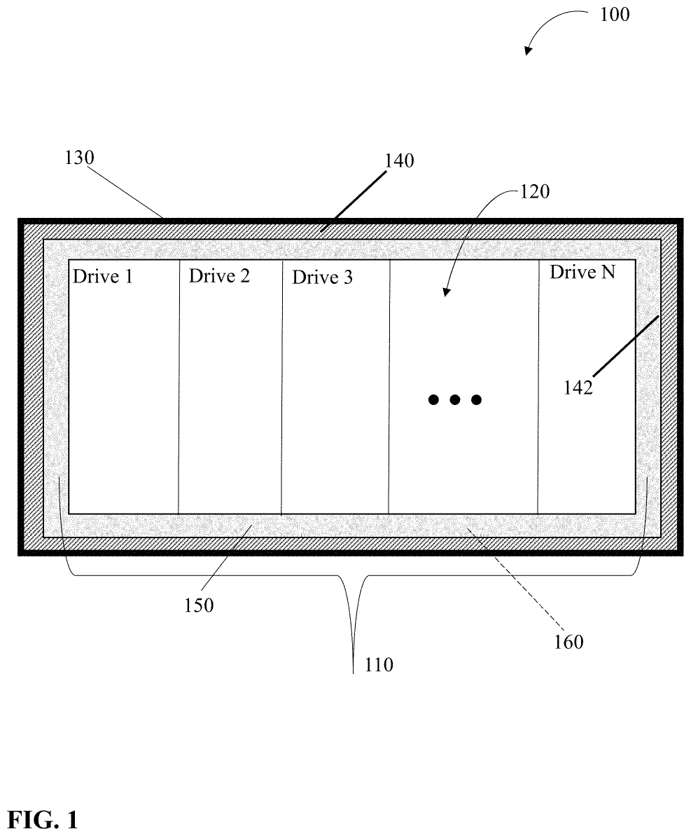

Referring to FIG. 1, a block schematic diagram is presented illustrating a computer system enclosure 100, herein the enclosure 100, in accordance with some embodiments of the present disclosure. The enclosure 100 houses a plurality of drives 1, 2, 3, . . . , N, collectively referred to as drives 110, within a compartment 120. The compartment 120 is at least partially defined through an enclosure casing 130 extending about a sheet metal cage 140 that structurally supports the drives 110. The enclosure 100 also includes a tailored material in a micro-lattice configuration, i.e., a tuned micro-lattice material 150 that is configured specifically for the enclosure 100 as discussed further herein, where the terms “tailored,” “tuned,” and “engineered” are used interchangeably herein. In some embodiments, the enclosure 100 has any configuration that enables operation of the tuned micro-lattice material 150 as described herein, from small electronic devices in an automobile to large computer server rooms, where the combined internal and/or external EMI/RFI attenuation, external vibration dampening, and heat transport are realized. In some embodiments, the tuned micro-lattice material 150 is formed as a gasket coupled to either the sheet metal cage 140 or an enclosure access door (not shown). In some embodiments, the tuned micro-lattice material 150 is configured as a coating that extends about any percentage of an interior surface 142 of the sheet metal cage 140 to provide the desired effects of the tuned micro-lattice material 150.

In some embodiments, rather than the tuned micro-lattice material 150, the enclosure 100 includes a tailored, i.e., tuned composite metallic foam 160 that is configured specifically for the enclosure 100 as discussed further herein. In a manner similar to the tuned micro-lattice material 150, in some embodiments, the enclosure 100 has any configuration that enables operation of the tuned composite metallic foam 160 as described herein, from small electronic devices in an automobile to large computer server rooms, where the combined internal and/or external EMI/RFI attenuation, external vibration dampening, and heat transport are realized. In some embodiments, the tuned composite metallic foam 160 is manufactured as a gasket that is applied to either the sheet metal cage 140 or the enclosure access door. In some embodiments, the tuned composite metallic foam 160 is configured as a coating that extends about any percentage of the interior surface 142 of the sheet metal cage 140 to provide the desired effects of the tuned composite metallic foam 160. In some embodiments, a combination of the tuned micro-lattice material 150 and the tuned composite metallic foam 160 are used in the enclosure 100.

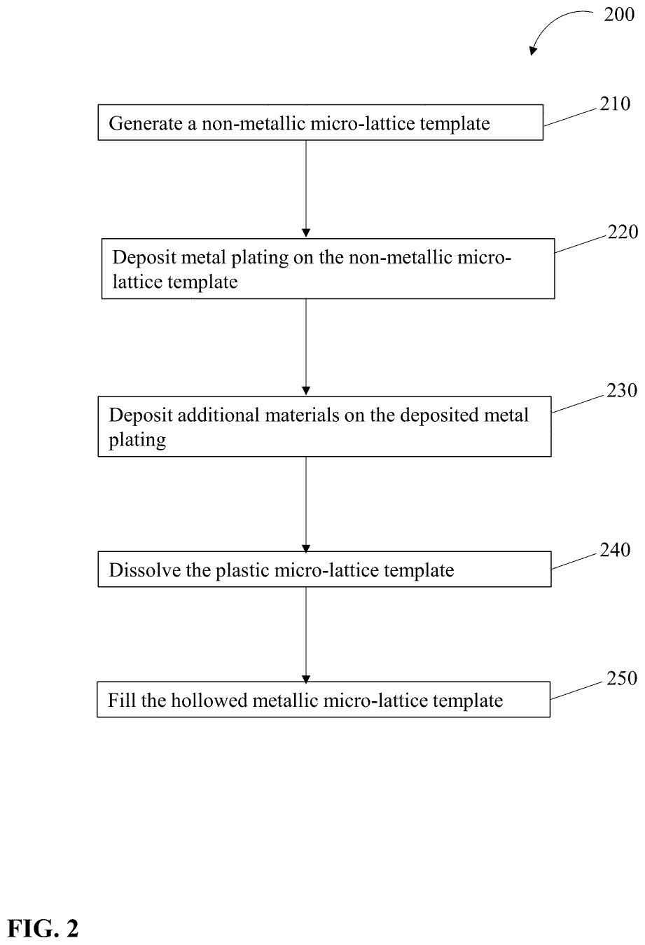

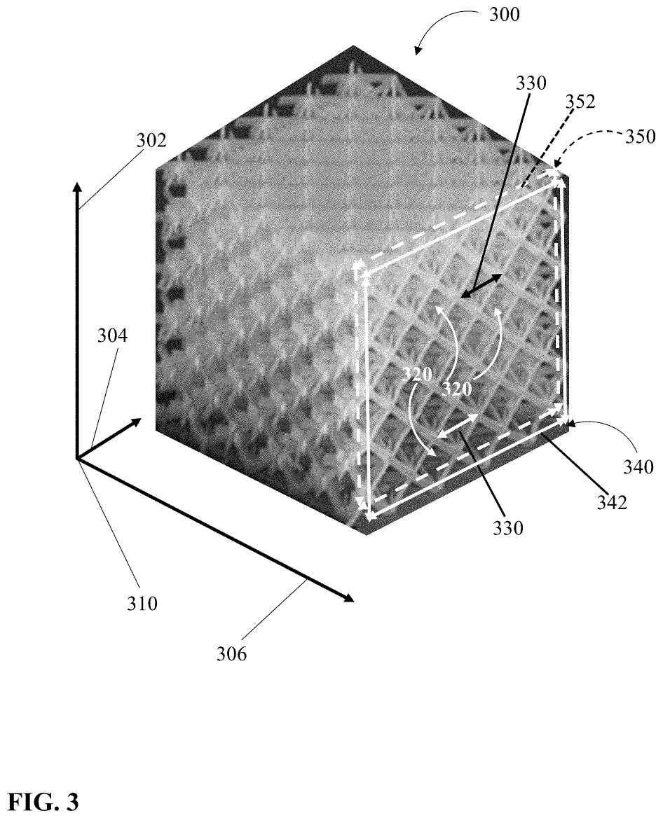

Referring to FIG. 2, a flowchart is presented illustrating a process 200 for manufacturing the tuned micro-lattice material 150 (shown in FIG. 1), in accordance with some embodiments of the present disclosure. In general, the process 200 is directed toward manufacturing a tailored, precision gasket that includes a metallic micro-lattice. The process 200 includes generating 210 a non-metallic micro-lattice template 300 such as that shown in FIG. 3.

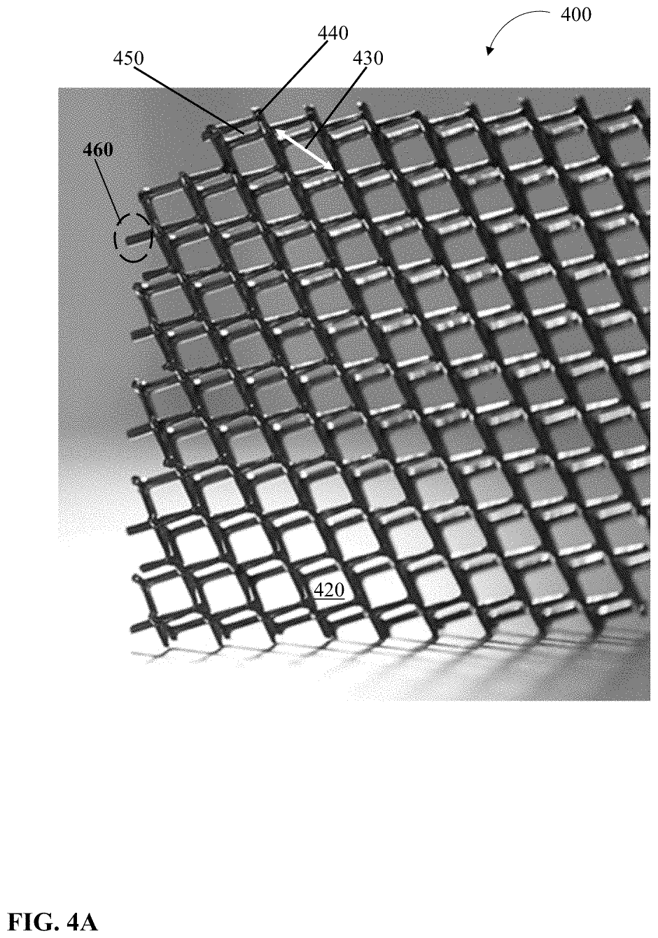

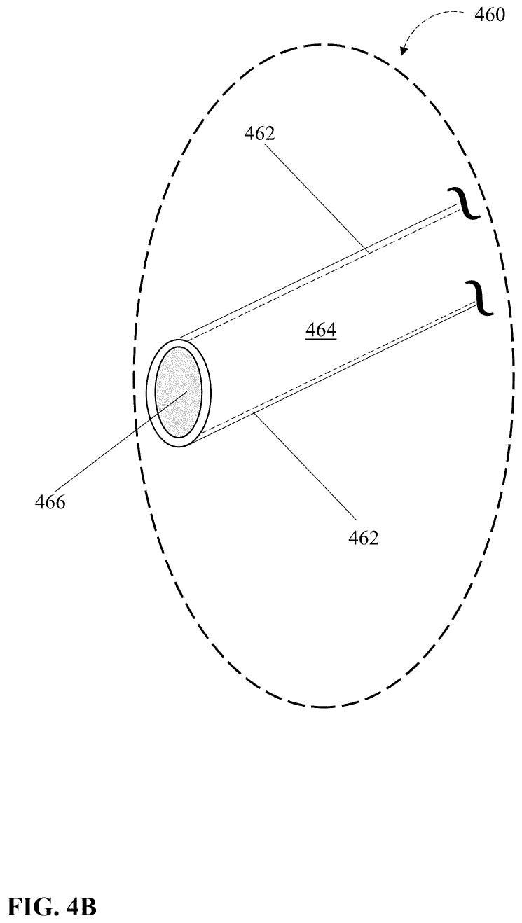

Referring to FIG. 3, a block schematic diagram is presented illustrating the non-metallic micro-lattice template 300, in accordance with some embodiments of the present disclosure. The non-metallic micro-lattice template 300 is shown extending in the three orthogonal spatial dimensions 302, 304, and 306 that define an origin 310. In some embodiments, the non-metallic micro-lattice template 300 includes a plurality of substantially rectangular lattice openings, or pores 320, each with a diagonal length 330. In some embodiments, the dimensions of the non-metallic micro-lattice template 300 are in units of micrometers. In some embodiments, the diagonal lengths 330 are substantially similar. In some embodiments, the diagonal lengths 330 vary. In some embodiments, the substantially rectangular lattice pores 320 of a first layer 340 of the one or more metallic materials in a micro-lattice configuration (as defined by the solid arrows 342) are offset from those of a second layer 350 of the one or more metallic materials in a micro-lattice configuration (as defined by the dashed arrows 352), where the offset is continued as the subsequent layers of the one or more metallic materials in a micro-lattice configuration (not shown) are formed progressing along the axis 306 toward the origin 310. Such offsets are further shown in FIG. 4. In some embodiments, there are no offsets of the rectangular lattice pores 320.

The sizes and configurations of the rectangular lattice pores 320 and the respective diagonal lengths 330 are tailored for the intended application to balance the airflow therethrough to provide the desired heat transport rates and paths from the enclosure, EMC shielding, and mechanical integrity (including vibration dampening) of the computer system enclosure 100 (see FIG. 1). Such configurations include the predetermined porosity and pore size to provide the desired heat transport as a function of the airflow impedance. Such configurations also include the desired thickness of the lattice structure to provide the desired mechanical integrity of the tuned micro-lattice material 150. In some embodiments, the lattice openings have any configuration that enables operation of the non-metallic micro-lattice template 300 as described herein, including, without limitation, ovular, circular, and trapezoidal.

Continuing to refer to FIGS. 2 and 3, the non-metallic micro-lattice template 300 is generated 210 through any three-dimensional printing method that enables operation of the non-metallic micro-lattice template 300 as described herein, including, without limitation, stereolithography, continuous liquid interphase printing (CLIP), material jetting, material extrusion, self-propagating waveguide formation, and the like. The materials used to generate the non-metallic micro-lattice template 300 are any polymer materials, e.g., plastics and elastomers that enable the process 200 as described herein.

In one or more embodiments, one or more layers of a metallic plating is deposited 220 on the non-metallic lattice template 300. In some embodiments, one or more plating materials are deposited through one or more mixtures and one or more spray applications including, without limitation, employment of electroless plating methods. In some embodiments, any electroplating/electrospraying methods that enable the process 200 as described herein are used. In some embodiments, the metal plating includes one of electroless nickel and electroless copper. For those embodiments where only one material is deposited on the non-metallic lattice template 300, one or more layers may be formed thereon. In some embodiments, additional metals or coatings are deposited 230 onto the electroless layer for additional corrosion protection or to increase electrical conductivity. For some those embodiments where more than one material is deposited on the non-metallic lattice template 300, the materials are deposited in one or more layers simultaneously through a mixture. In some embodiments, where more than one material is deposited on the non-metallic lattice template 300, the materials are deposited in one or more layers serially. Accordingly, one or more layers of one or more metallic plating and additional materials are deposited on the non-metallic micro-lattice template 300.

In at least some embodiments, the non-metallic lattice template 300 is dissolved 240 through any selective material dissolving method that enables operation of the process 200 as described herein, including, without limitation, etching techniques, thereby forming one or more voids (see FIG. 4B) defined within the metallic plating. The dissolving step 240 results in a metallic micro-lattice 400 (as shown in FIG. 4A) that includes the voids (see FIG. 4B) within the metallic micro-lattice 400. In some embodiments, to further enhance the vibration dampening properties, the initial non-metallic lattice template 300 is made of an elastomer material that is not dissolved once the metallic plating is used to coat the elastomer lattice. Accordingly, in some embodiments, the dissolving step 240 is optional.

Referring to FIG. 4A, a block schematic diagram is presented illustrating a metallic micro-lattice 400, in accordance with some embodiments of the present disclosure. The metallic micro-lattice 400 includes the rectangular lattice openings 420 and the respective diagonal lengths 430 on each of the first layer 440 that are offset from those of the second layer 450. The dimensional relationships between the components of the hollowed metallic micro-lattice 400 shown in FIG. 4 and the similarly numbered components of the non-metallic micro-lattice 300 of FIG. 3 are similar, taking into account the metallic overlay of the non-metallic micro-lattice 300.

Referring again to FIG. 2 (in conjunction with FIGS. 3 and 4), the hollowed metallic micro-lattice 400 is filled 250 with additional metallic plating or another material to optimize the mechanical properties of the tuned micro-lattice material 150 (see FIG. 1). For example, and without limitation, to increase the vibration damping properties, the hollow metallic micro-lattice 250 is filled with an elastomeric material (see FIG. 4B). Is some embodiments, the filling 250 step includes mechanically or chemically exposing an opening in the hollowed metallic micro-lattice 400 to allow an elastomeric material (466 in FIG. 4) to fill the hollow spaces (464 in FIG. 4). The metallic micro-lattice 400 us then be submerged in a vat of the elastomeric material and vacuum impregnation is used to fill the hollow cavity 464. The elastomer 466 is solidified in place by chemically curing.

In some embodiments, to further enhance the vibration dampening properties, the initial non-metallic lattice template 300 is made of an elastomer material that is not dissolved once the metallic plating is used to coat the elastomer micro-lattice 300. In some embodiments, the elastomer materials are a thermoplastic elastomer (TPE), sometimes referred to as thermoplastic rubbers, for example, and without limitation, a thermoplastic polyurethane (TPU). In some embodiments, the hollowed metallic micro-lattice 400 is filled 250 with the same materials as that applied in method step 230. Referring to FIG. 4B, a block schematic diagram is presented illustrating a portion 460 of the tuned micro-lattice material 150 (see FIG. 1), in accordance with some embodiments of the present disclosure. The hollowed metallic micro-lattice 400 (see FIG. 4A) includes an outer metallic wall 462 formed from the one or more layers of the metallic overlay defining the void 464 that is at least partially filled with the filler material 466, e.g., the elastomeric material. Accordingly, the micro-lattice material 150 includes one or more metallic materials defining a micro-lattice configuration, where the one or more metallic materials extend over at least a portion of an elastomeric material.

The resultant tuned micro-lattice material 150 is tailored for one or more specific uses. Such tailoring/tuning includes manufacturing the tuned micro-lattice material 150 with the sizes and configurations of the rectangular lattice openings 420 and the respective diagonal lengths 430 that are tailored for the intended applications to balance the airflow therethrough to provide the desired heat transport, EMC shielding, and mechanical integrity (including vibration dampening) of the computer system enclosure 100. Such configurations include the engineered porosity and pore size to provide the desired heat transport as a function of the airflow impedance. Such configurations also include the engineered thickness of the lattice structure to provide the desired mechanical integrity of the tuned micro-lattice material 150 Accordingly, the tuned micro-lattice material 150 in the form of, e.g., and without limitation, an EMC gasket is manufactured with tailorable vibration dampening/isolation characteristics, airflow impedance, and EMI/RFI attenuation in an engineered balance of those three properties.

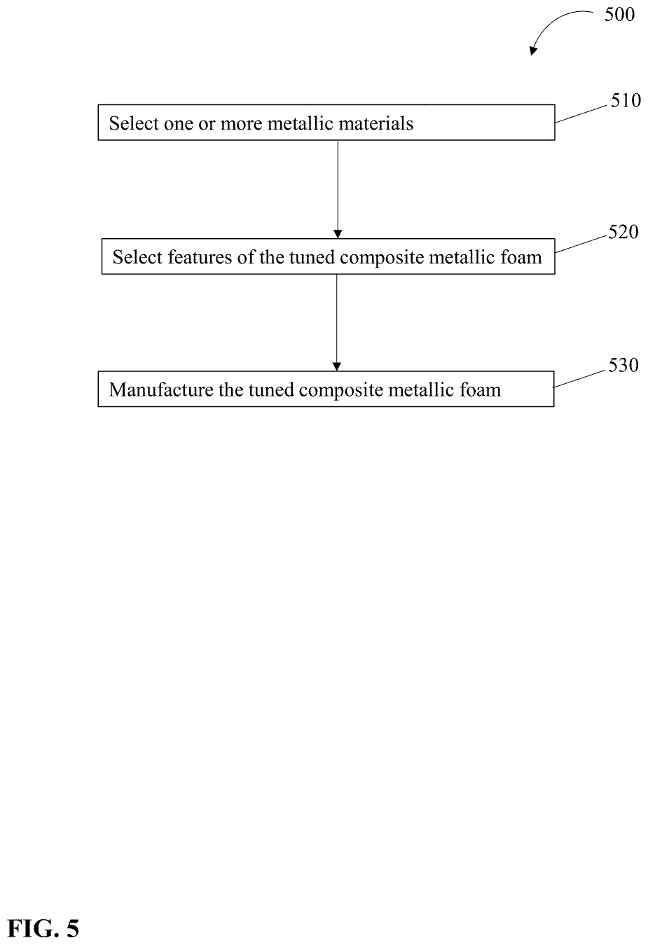

Referring to FIG. 5, a flowchart is presented illustrating a process 500 for manufacturing the tuned composite metallic foam 160 (see FIG. 1), in accordance with some embodiments of the present disclosure. The process 500 includes selecting 510 one or more metallic materials to be used in manufacturing the tuned composite metallic foam 160. The selected metallic materials include, without limitation, one or more aluminum (AL), copper (Cu), nickel (Ni), and steel alloys. Accordingly, any combination of metallic materials that enable operation of the tuned composite metallic foam 160 as described herein is used, including without limitation, aluminum-steel, nickel superalloy, steel-steel, etc.

In at least some embodiments, the physical features (or characteristics) of the tuned composite metallic foam 160 are selected 520. The physical features/characteristics include, without limitation, which portions of the foam have an open-cell configuration with an engineered percent porosity and pore size, which portions of the foam have a closed-cell configuration with a predetermined density, and a thickness of the foam gasket. The more porous open-cell portions have a lower airflow impedance than the closed-cell portions which have a very high airflow impedance. The term “composite” applies to the combination of open-cell and closed-cell porosities. Accordingly, the combination and placement of the open-cell and closed-cell portions provide the overall engineered airflow impedance of the tuned composite metallic foam 160 as well as the tailored impedance to vibration transmission and tailored EMI/RFI attenuation.

In some embodiments, the tuned composite metallic foam 160 is manufactured 530 through a process such as, and without limitation, the hollow sphere structures by powder metallurgical method as is known in the art of manufacturing technologies, herein referred to as the hollow spheres method. In some embodiments, any method of manufacturing that enables operation of the tuned composite metallic foam 160 as described herein is used.

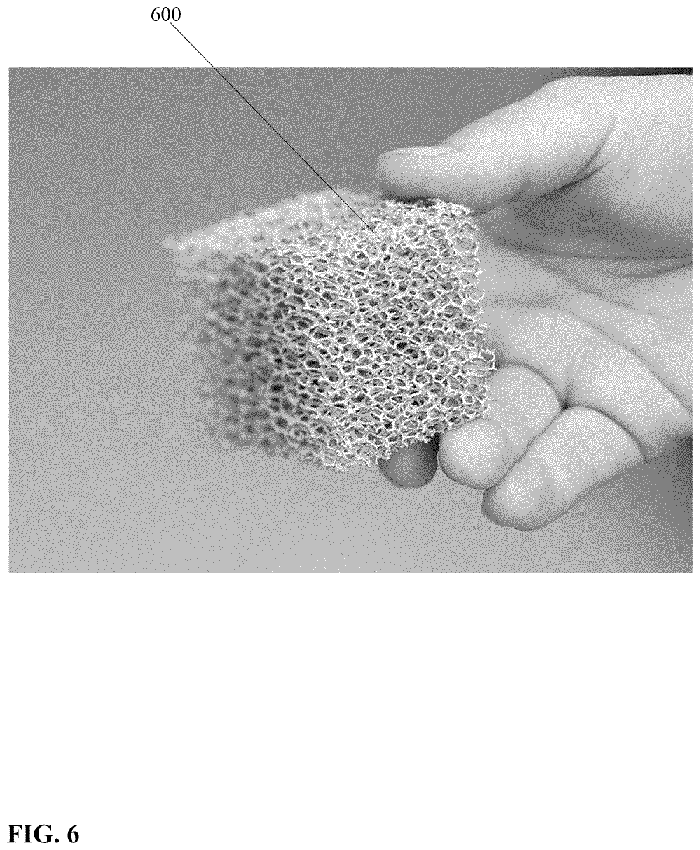

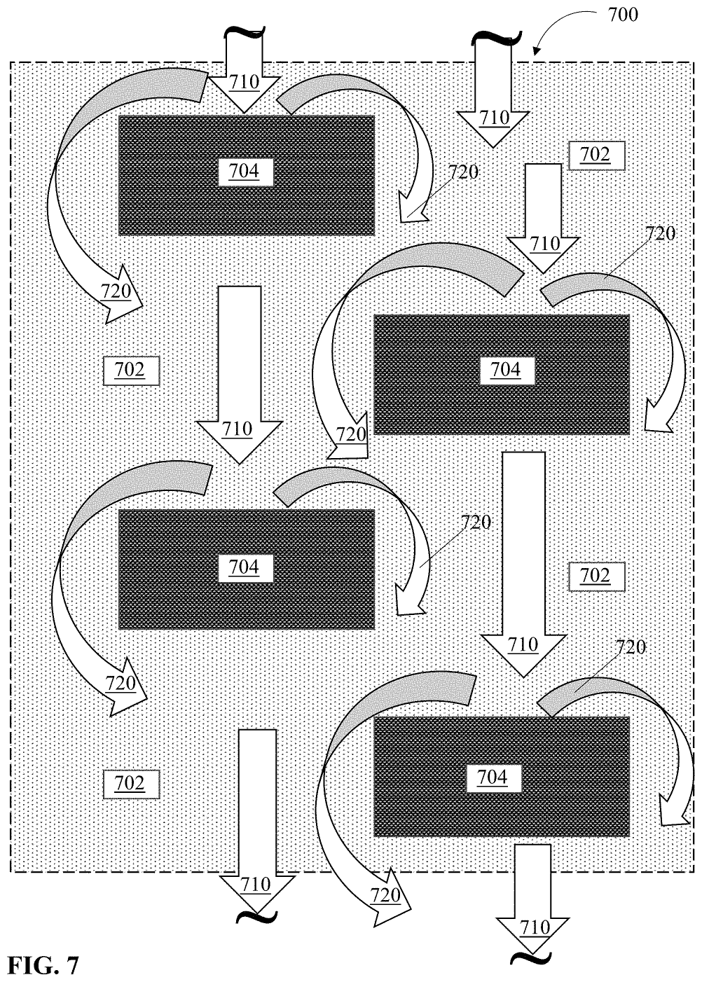

Referring to FIG. 6, a diagram is presented illustrating a manufactured tuned composite metallic foam 600 that is manufactured through the process 500 (see FIG. 5), in accordance with some embodiments of the present disclosure. Also, referring to FIG. 7, a block schematic diagram is presented illustrating a cutaway and amplified view of the manufactured tuned composite metallic foam 700 (shown as 600 in FIG. 6), in accordance with some embodiments of the present disclosure. More specifically, the tuned composite metallic foam 700 defines a portion of an EMC gasket with balanced and tailored characteristics that include vibration isolation characteristics, airflow impedance, and EMI/RFI attenuation. Also, specifically, to facilitate balancing the three tailored characteristics within the engineered composite metallic foam 700, the foam 700 is manufactured with portions 702 of an open-cell porosity and portions 704 of a closed-cell porosity. The use of rectangular images is for ease of description and is non-limiting, where any configuration of the tuned composite metallic foam 700 that enables operation of the foam 700 as described herein is manufactured. The open-cell porosity portions 702 have an engineered porosity to facilitate a desired range of airflows 710 therethrough. The closed-cell porosity portions 704 have an engineered porosity to reduce airflow therethrough, thereby deflecting the airflows 720. The overall effect is to provide an engineered impedance to the airflows 710 through the ratio of two types of porosity and the overall relative density that is tailored by varying the starting density of the hollow spheres and the extent of densification during consolidation.

In some embodiments, the open-cell porosity portions 702 have varying porosities throughout the tuned composite metallic foam 700 to further engineer the airflow characteristics therethrough with greater granularity. In some embodiments, the closed-cell porosity portions 704 also have varying porosities throughout the tuned composite metallic foam 700 to further engineer the airflow characteristics therethrough with greater granularity. The engineered airflows at least partially define the engineered heat transport through the tuned composite metallic foam 700 as well as the mechanical properties thereof, including, without limitation, vibration dampening, tensile strength, and moldability. In at least some embodiments, the metallic material selections 510 and features selections 520 (see FIG. 5) compliment the tuned composite metallic foam 700 to meet the desired heat transport, vibration dampening, and EMI/RFI attenuation characteristics. Furthermore, if desired, sound damping properties of the tuned composite metallic foam 700 are also engineered through the selection and manufacturing methods disclosed herein. Accordingly, the engineering design and manufacturing methods disclosed herein facilitate using both closed-cell and opened-cell porosities to tailor the tuned composite metallic foam 700 as necessary for each particular employment thereof.

As described herein, the properties of a metallic foam can be varied by controlling the percentage of the openings therein. As a non-limiting example, the properties of one embodiment of a copper-based tuned composite metallic foam 700 are compared to bulk solid copper alloy 770. Specifically, the modulus of elasticity of the copper-based tuned composite metallic foam 700 is approximately 22 gigapascal (GPa) that indicates a greater elasticity and a lesser stiffness than that of bulk solid copper alloy 770 at approximately 124 GPa. Also, the mechanical dampening factor of the foam 700 is within a tunable unitless range of approximately 0.017*10⁻³ through approximately 2.2*10⁻³ as compared to the copper 770 of approximately 2.0*10⁻⁴. Therefore, the mechanical dampening factor of the foam 700 is greater than that of the copper 770. Furthermore, the thermal conductivity of the foam 700 is within a tunable range of approximately 7 Watts per meter per degree Kelvin (W/m-K) to approximately 43 W/m-K as compared to that of the copper 770 of approximately 29.4 W/m-K. Therefore, the thermal conductivity of the foam 700 may be tuned to facilitate heat transport in conjunction with the tunable airflow. In addition, the electrical resistivity of the foam 700 is within a tunable range of approximately 2.8*10⁻⁸ ohm-centimeters (ohm-cm) to approximately 1.66*10⁻⁷ ohm-cm (at approximately 20 degrees Celsius) as compared to that of the copper 770 of approximately 3/24*10⁻⁵ ohm-cm. Therefore, the resistance to current flow in the foam 700 is less than the resistance to current flow of the copper 770. Accordingly, the tuned composite metallic foam 700 includes one or more physical features including engineered locations of a plurality of the first portions 702 within the tuned composite metallic foam 700, engineered locations of a plurality of the second portions 704 the tuned composite metallic foam 700, and a thickness of the tuned composite metallic foam 700 applied to the enclosure 100 (see FIG. 1).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A material for an enclosure that houses one or more electronic devices comprising:
a tuned micro-lattice comprising:
one or more metallic materials defining a micro-lattice configuration, wherein the material for the enclosure is one or more of a gasket and a coating that extends over a least a portion of an interior portion of the enclosure.

2. The material of claim 1, wherein:
the one or more metallic materials are deposited over a non-metallic micro-lattice template, wherein the non-metallic micro-lattice template is at least partially dissolved, thereby defining a void within the deposited one or more metallic materials.

3. The material of claim 2, wherein:
the void is at least partially filled with an elastomeric material.

4. The material of claim 1, wherein:
the one or more metallic materials are deposited over an elastomeric micro-lattice template.

5. The material of claim 1, wherein:
one or more additional materials are deposited on the one or more metallic materials.

6. The material of claim 1, wherein the tuned micro-lattice comprises:
a first layer of the one or more metallic materials in the micro-lattice configuration; and
and a second layer of the one or more metallic materials in the micro-lattice configuration, wherein the second layer is at least partially offset from the first layer.

7. The material of claim 1, wherein the tuned micro-lattice is engineered for one or more characteristics comprising:
thermal transport from the enclosure to an external environment;
dampening of vibration external to the enclosure; and
electromagnetic compatibility (EMC).

8. The material of claim 7, wherein:
the tuned micro-lattice is engineered for balancing a plurality of the one or more characteristics.

9. The material of claim 7, wherein the EMC characteristic comprises:
attenuation of emissions from the enclosure of internally-generated electromagnetic interference (EMI) and radio frequency interference (RFI); and
attenuation of emissions into the enclosure from externally-generated EMI and RFI.

10. A material for an enclosure that houses one or more electronic devices comprising:
a tuned composite metallic foam comprising one or more metallic materials, wherein a first portion of the foam has a first porosity and a second portion of the foam has a second porosity, wherein the material for the enclosure is one or more of a gasket and a coating that extends over a least a portion of an interior portion of the enclosure.

11. The material of claim 10, wherein:
the tuned composite metallic foam includes one or more physical features comprising:
a location of a plurality of the first portions within the tuned composite metallic foam;
a location of a plurality of the second portions the tuned composite metallic foam; and
a thickness of the material applied to the enclosure.

12. The material of claim 11, wherein:
each first portion of the plurality of first portions defines an open-cell configuration with the first porosity and a first pore size.

13. The material of claim 11, wherein:
each second portion of the plurality of second portions defines a closed-cell configuration with a predetermined density.

14. The material of claim 10, wherein the tuned composite metallic foam is engineered for one or more characteristics comprising:
thermal transport from the enclosure to an external environment;
dampening of vibration external to the enclosure; and
electromagnetic compatibility (EMC).

15. The material of claim 14, wherein:
the tuned composite metallic foam is engineered for balancing a plurality of the one or more characteristics.

16. The material of claim 14, wherein the EMC characteristic comprises:
attenuation of emissions from the enclosure of internally-generated electromagnetic interference (EMI) and radio frequency interference (RFI); and
attenuation of emissions into the enclosure from externally-generated EMI and RFI.

17. A method for manufacturing a material for an enclosure that houses one or more electronic devices comprising:
generating a metallic micro-lattice structure; and
filling at least a portion of the metallic micro-lattice structure with an elastomeric material.

18. The method of claim 17, wherein the generating the metallic micro-lattice structure comprises:
generating a non-metallic micro-lattice template; and
depositing a metal plating on the non-metallic micro-lattice template.

19. The method of claim 17, wherein the filling the at least a portion of the metallic micro-lattice structure with the elastomeric material comprises:
dissolving at least a portion of the non-metallic micro-lattice template, thereby defining a void within the deposited metal plating; and
filling the void with the elastomeric material.

20. The method of claim 17, wherein the filling the at least a portion of the metallic micro-lattice structure with the elastomeric material comprises:
generating an elastomeric micro-lattice template; and
depositing a metal plating on the elastomeric micro-lattice template.
